(19) United States
(12) Patent Application Publication
(10) Pub. No.: US 2025/0201614 A1
(43) Pub. Date: Jun. 19, 2025

(54) METHOD OF PROVIDING A WAFER

(71) Applicant: SMART PHOTONICS HOLDING B.V., Eindhoven (NL)

(72) Inventors: Alonso Jesús MILLÁN-MEJÍA, Eindhoven (NL); Tsjerk Hans HOEKSTRA, Eindhoven (NL); Angel Metodiev SAVOV, Eindhoven (NL); Christine DE NOOIJER, Eindhoven (NL)

(21) Appl. No.: 19/054,515

(22) Filed: Feb. 14, 2025

Related U.S. Application Data
(63) Continuation of application No. PCT/EP2023/073855, filed on Aug. 30, 2023.

(30) Foreign Application Priority Data
Aug. 31, 2022 (GB) 2212686.6

(51) Int. Cl. H01L 21/683; H01L 21/768

(52) U.S. Cl. CPC H01L 21/6831; H01L 21/768

(57) ABSTRACT

A method comprising: providing an electrically-insulative wafer comprising a first surface, and a second surface for processing; and providing a layer on the first surface. The layer is non-metallic, electrically-conductive, and for electrostatically clamping to an electrostatic chuck.

### CROSS REFERENCE TO RELATED APPLICATIONS

This application is a continuation under 35 U.S.C. § 120 of International Application No. PCT/EP2023/073855, filed Aug. 30, 2023 which claims priority to United Kingdom Application No. GB 2212686.6, filed Aug. 31, 2022 under 35 U.S.C. § 119(a). Each of the above-referenced patent applications is incorporated by reference in its entirety.

### BACKGROUND

An electrostatic chuck is used to support a wafer during fabrication of a circuit on the wafer. It is desirable to improve this technique for fabricating photonic integrated circuits.

### BRIEF DESCRIPTION OF THE DRAWINGS

FIG. 1 is a flow diagram of a method in accordance with examples;

FIGS. 2A, 2C, 2E, 2G, 2H, and 2I show schematically a side cross-section of structures during a method in accordance with examples;

FIG. 2B shows schematically a top plan view of the structure of FIG. 2A;

FIGS. 2D and 2F show schematically a bottom plan view of the structures of FIGS. 2E and 2G respectively;

FIGS. 3 to 4B show schematically a side cross-section of various structures during methods of further examples;

FIG. 5 shows schematically a bottom plan view of a structure during a method of further examples.

### DETAILED DESCRIPTION

In examples to be described, a method comprises providing an electrically-insulative wafer. A layer is provided on a first surface (e.g., of an underside) of the wafer. The layer is non-metallic, electrically conductive, and for electrostatically clamping to an electrostatic chuck. A second surface (e.g., of an upperside) of the wafer is for processing, for example to fabricate a circuit such as a photonic integrated circuit (PIC). Examples herein also relate to methods of fabricating a device, a structure obtained by a method described herein, and a device obtained by a method described herein.

Electrostatically clamping a wafer to an electrostatic chuck is used to reduce or prevent displacement (e.g., rotation) of a wafer during processing of a surface of the wafer e.g. to fabricate a circuit. Such electrostatic clamping can cause less damage to the wafer than other clamping methods. However, electrostatic clamping may still damage the wafer and/or a circuit being fabricated. It is found that such damage may be due to interactions between an electrical field applied for electrostatic clamping and processing of the wafer, e.g., dry etching or plasma etching for fabricating a circuit. Such damage may be called electrostatic damage. For example, electrostatic clamping combined with plasma etching is found to electrostatically damage and/or deform the wafer.

It has been realised that using a non-metallic and electrically conductive layer on the first surface of the wafer, reduces or even prevents electrostatic damage, as will be explained in more detail in the examples below. By reducing such electrostatic damage, the performance, reliability and/or reproducibility of a circuit fabricated on the wafer may be improved. It has also been realised that using a non-metallic layer on the first surface of the wafer, reduces or even prevents contamination of a circuit being fabricated and/or the wafer, for example during etching for circuit fabrication. This is in contrast to using a metallic layer which is susceptible to etching during processing of the second surface. Plus, depending on a particular etchant used during processing of the second surface, the material of such a layer may reduce or avoid the need to replace the layer on the first surface which would otherwise require un-clamping and re-clamping the wafer and interrupts fabrication. Reducing or avoiding the need to replace the layer may reduce the time needed for circuit fabrication, reducing the cost of circuit fabrication.

Before describing examples in more detail, it is useful to elaborate on the meaning of a couple of terms used herein. Further details of various terms used herein are explained at the end of the description.

Electrostatic clamping of a wafer clamps a wafer to an electrostatic chuck by applying an electric field to the electrostatic chuck and bringing the wafer and the electrostatic chuck together. The electric field causes a portion of the wafer and a portion of the electrostatic chuck to become oppositely charged and electrostatically attract, clamping the wafer to the electrostatic chuck. A clamping force between the wafer and the chuck increases with an increase in the voltage between the chuck and the wafer.

A metallic layer referred to herein is a layer comprising a metallic material. A metallic layer as the layer on the first surface of the wafer is outside the scope of the examples described herein. A metallic material is considered to be a material formed with metallic bonds between particles of the material. A metallic bond is an electrostatic attraction between delocalised conduction electrons and positively charged ions of metal elements. In contrast a non-metallic material is any material which is not a metallic material. Hence a non-metallic layer has properties of the non-metallic material of which it is formed. More particularly, a non-metallic material of the layer on the first surface is a non-metallic electrically-conductive material, such as a non-metallic electrically-conductive material comprising at least one metal element. For example, the layer comprises iron-doped indium phosphide (Fe-InP).

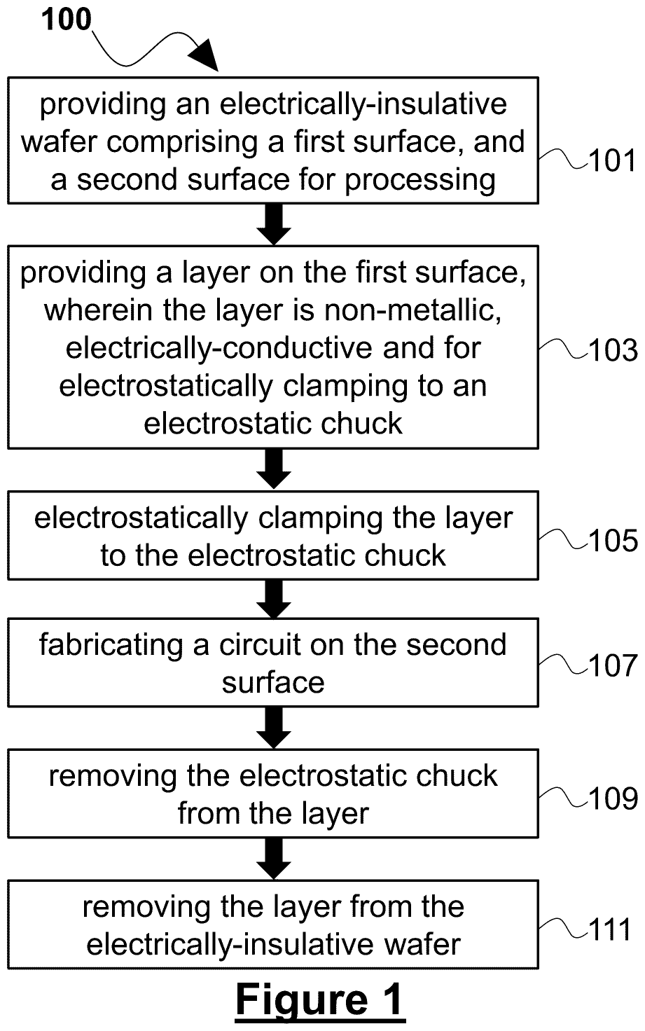

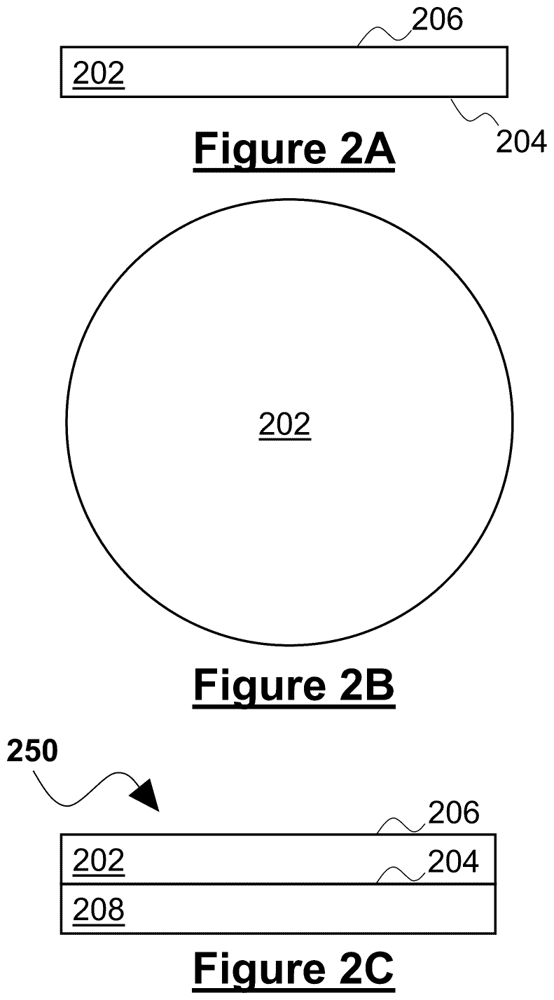

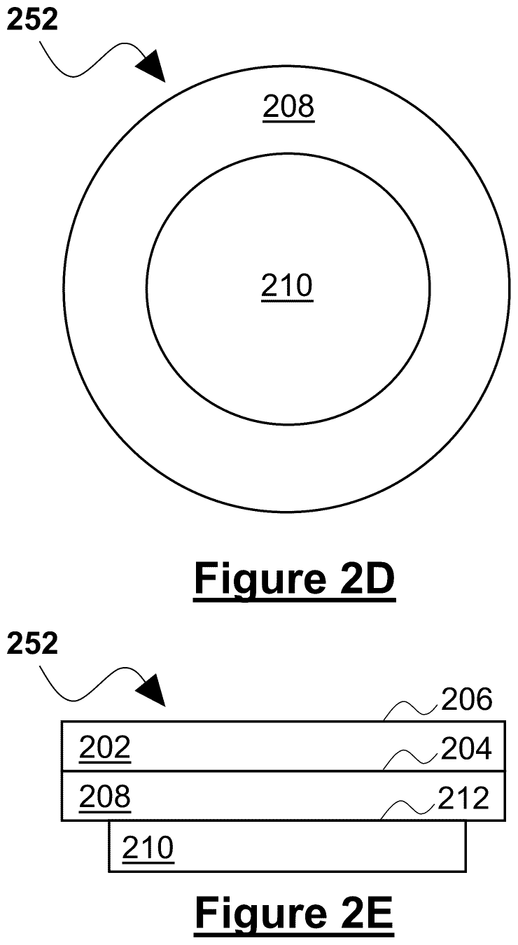

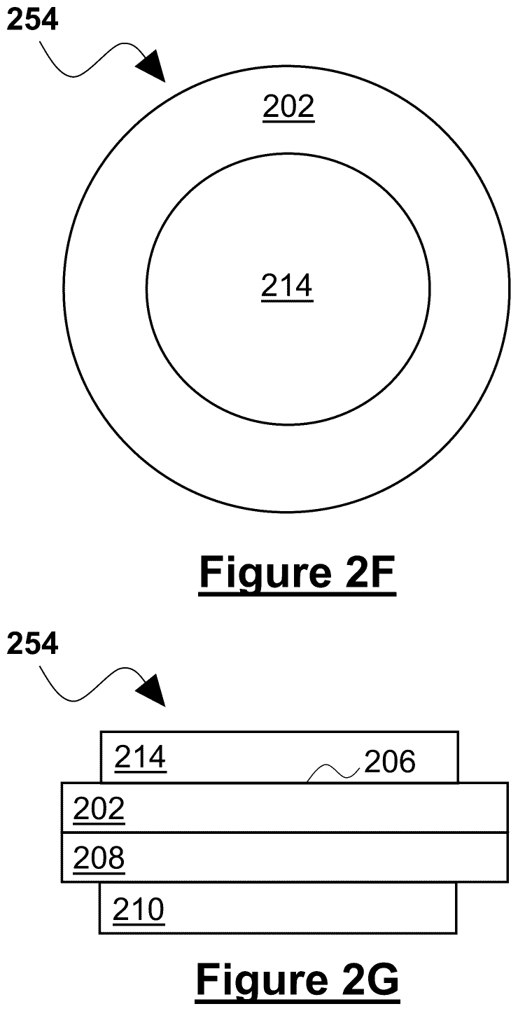

A general description of the examples herein is now given with reference to FIGS. 1 to 2I. FIG. 1 is a flow diagram of a method 100 in accordance with examples. FIGS. 2A, 2C, 2E, 2G, 2H, and 2I show schematically a side cross-section of structures during a method according to examples. FIG. 2B shows a top plan view of the structure of FIG. 2A. FIGS. 2D and 2F show a bottom plan view of the structure of FIGS. 2E and 2G respectively. The method 100 comprises providing 101 an electrically-insulative wafer 202 with a first surface 204 and a second surface 206. The second surface 206 is for processing e.g. to fabricate a circuit. The method 100 then comprises providing 103 a layer 208 on the first surface 204—see FIG. 2C. The layer 208 is non-metallic and electrically-conductive, and for electrostatically clamping to an electrostatic chuck. FIG. 2C also shows a structure 250 obtained by providing 103 a layer 208 on the first surface 204.

The method 100 then comprises electrostatically clamping 105 the layer 208 to the electrostatic chuck 210—see FIGS. 2D and 2E. A surface 212 of the layer 208 is in contact with the with the electrostatic chuck 210 and electrostatically clamped to the electrostatic chuck 210. In other examples not shown, the layer and/or a surface of the layer is not in contact with the electrostatic chuck whilst the layer is electrostatically clamped to the electrostatic chuck. In FIG. 2D and 2E, the layer 208 is between the surface 212 of the layer 208 and electrically-insulative wafer 202. The electrostatic chuck 210 is electrostatically clamped to the layer 208 by applying a voltage to at least one of the electrostatic chuck 210 or the layer 208 and bringing the layer 208 and the electrostatic chuck 210 together. Several different electrical configurations are envisaged for electrostatic clamping, as will be described later. Before and after electrostatically clamping the layer 208 to the electrostatic chuck 210, the first surface 204 and the second surface 206 are planar. In other examples not shown the first surface and the second surface are planar before electrostatically clamping the layer to the electrostatic chuck and at least one of the first surface or the second surface is not planar after electrostatically clamping the layer to the electrostatic chuck. The first surface 204 and the second surface 206 being planar may increase the performance of a circuit fabricated on the second surface 206, the repeatability of fabrication of a circuit on the second surface 206 and/or the reliability of a circuit on the second surface 206. FIGS. 2D and 2E also show a structure 252 obtained by electrostatically clamping 105 the layer 208 to the electrostatic chuck 210.

The method 100 then comprises fabricating 107 a circuit 214 on the second surface 206 of the electrically-insulative wafer 202—see FIGS. 2F and 2G. The layer 208 is electrostatically clamped to the electrostatic chuck 210 while fabricating the circuit 214. In other examples not shown the layer is removed from the electrostatic chuck for at least partly fabricating the circuit. Fabricating the circuit is described in detail later. FIGS. 2F and 2G also show a structure 254 obtained by fabricating 107 a circuit 214 on the second surface 206.

The method 100 then comprises removing 109 the electrostatic chuck 210 from the layer 208—see FIG. 2H. The layer 208 is on the first surface 204 of the wafer 202. In other examples not shown removing the electrostatic chuck from the layer comprises at least partly removing the layer from the wafer too. Further details of removing the electrostatic chuck are given later. FIG. 2H also shows a structure 256 obtained by removing 109 the electrostatic chuck 210 from the layer 208.

The method 100 then comprises removing 111 the layer 208 from the electrically-insulative wafer 202 (the transition from FIG. 2H or FIGS. 2F and 2G to FIG. 2I). In various examples the method comprises at least partly removing the layer 208 from the electrically-insulative wafer 202. FIG. 2I shows the layer 208 separated from the first surface 204 of the layer 202. In examples not shown, the layer is destroyed, physically altered, or chemically altered so that the layer is at least partly removed. Removing the layer from the wafer and/or at least partly removing the layer from the wafer may comprise at least one of etching, polishing, or grinding of the layer. Other techniques for removing or at least partly removing the layer are envisaged. FIG. 2I also shows an example structure 258 obtained by removing 111 the layer 208 from the wafer 202.

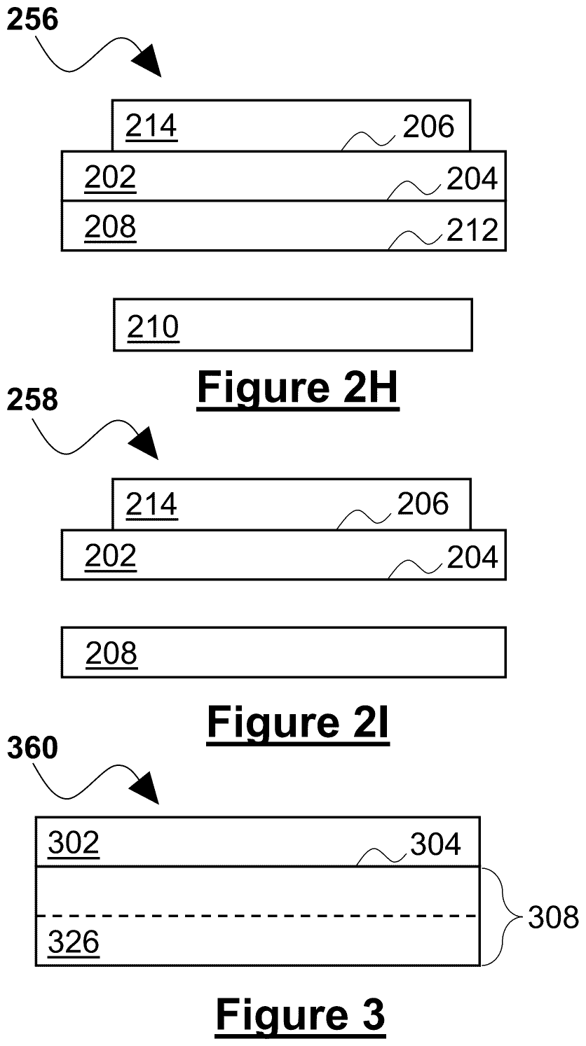

A description of further examples is now given with reference to FIG. 3. FIG. 3 shows schematically a side cross-section of a structure during a method of further examples. The layer 308 is on the first surface 304 of the electrically-insulative wafer 302. Where a feature in relation to FIG. 3 corresponds with a feature described using FIGS. 2A to 2I, a reference numeral is used which is 100 greater than the corresponding reference numeral used for FIGS. 2A to 2I (for example, 202 in FIG. 2C is 302 in FIG. 3); corresponding descriptions for such features apply here also. The layer 308 comprises a portion 326 (e.g., a sub-layer on an underside of the layer) which is an etch resist and hence is resistant to a given etchant (e.g., used for circuit fabrication). In examples not shown the layer comprises a plurality of portions (e.g., sub-layers) each acting as an etch resist. Other configurations or arrangements of the plurality of portions are envisaged. FIG. 3 also shows a structure 360 wherein layer 308 comprises a portion 326 which is an etch resist. A dashed line is used to indicate a border between portions of the layer.

A description of further examples is now given with reference to FIGS. 4A and 4B. FIGS. 4A and 4B show schematically a side cross-section of structures during a method of further examples. Where a feature in relation to FIGS. 4A and 4B corresponds with a feature described using FIGS. 2A to 2I, a reference numeral is used which is 200 greater than the corresponding reference numeral used for FIGS. 2A to 2I (for example, 202 in FIG. 2C is 402 in FIG. 4B); corresponding descriptions for such features apply here also. FIG. 4A shows providing a precursor 420 to the layer 408 and the wafer 402. The precursor comprises a first portion 416 and a second portion 418. The method then comprises doping of at least one of the first portion 416 or the second portion 418 to form the layer 408 from the first portion 416 of the precursor 420 and the wafer 402 from the second portion 418 of the precursor 420 (the layer 408 and the wafer 402 shown in FIG. 4B). Doping may comprise implantation of ions into at least one of the first portion 416 or the second portion 418, or diffusion of ions into at least one of the first portion 416 or the second portion 418. A person skilled in the art will be familiar such doping techniques. FIG. 4B shows the layer 408 formed from the first portion 416 and the wafer 402 formed from the second portion 418. FIG. 4B also shows a structure 462 obtained by doping of at least one of the first portion 416 or the second portion 418 to form the layer 408 from the first portion 416 and the wafer 402 from the second portion 418.

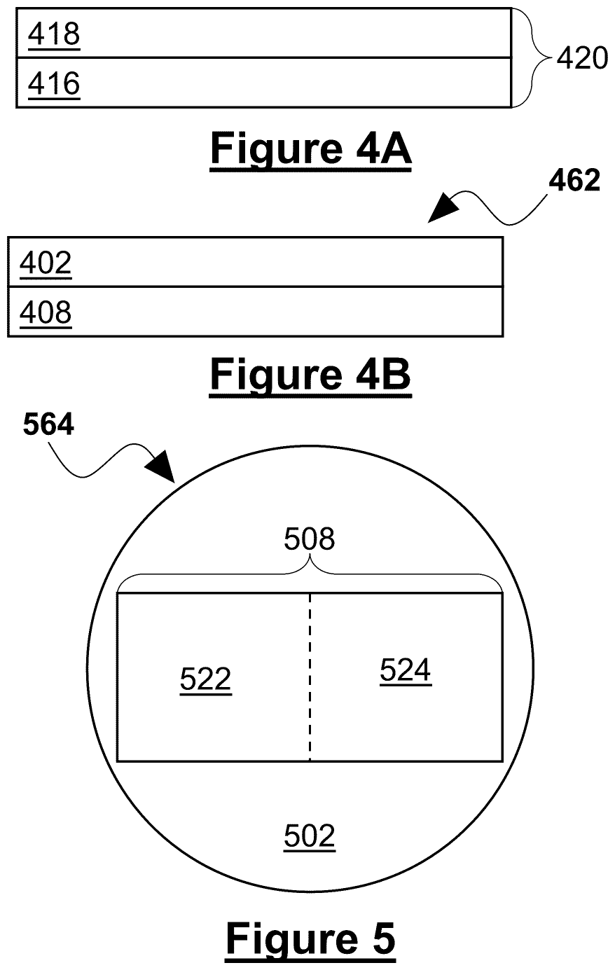

A description of further examples is now given with reference to FIG. 5. FIG. 5 shows schematically a bottom plan view of a structure during a method of further examples. Where a feature in relation to FIG. 5 corresponds with a feature described using FIGS. 2A to 2I, a reference numeral is used which is 300 greater than the corresponding reference numeral used for FIGS. 2A to 2I (for example, 202 in FIG. 2C is 502 in FIG. 5); corresponding descriptions for such features apply here also. The layer 508 comprises a first portion 522 and a second portion 524. The first portion 522 and the second portion 524 may be configured to reduce electrostatic damage of the electrically-insulative wafer 502, for example by reducing electric field gradients on the first surface or the second surface. The first portion 522 and the second portion 524 may be configured to reduce warping of the wafer 502 due to electrostatic damage. Other configurations or arrangements of the first portion 522 and the second portion 524 to the configuration shown, such as an array or mesh, are envisaged. FIG. 5 also shows a structure 564 obtained by providing the layer 508 on the first surface. A dashed line is used to indicate a border between portions of the layer.

A description of various examples herein is now given without reference to the Figures.

In various examples the layer on the first surface of the wafer improves the performance of a circuit fabricated on second surface of the wafer. For example, the layer may increase the repeatability of fabrication of a circuit on the second surface of the wafer. A stiffness of the layer may be greater than a stiffness of the wafer. A heat capacity of the layer may be greater than a heat capacity of the wafer. The greater stiffness and/or heat capacity of the layer compared to the wafer may reduce the effect of mechanical forces or temperature changes respectively on a circuit on the second surface of the wafer, which in turn may increase the performance of the circuit. A portion of the layer may be anti-reflective. Anti-reflectivity may be desirable for a PIC, for example to reduce losses due to light escaping the PIC. The material of the layer may also be chosen to be compatible with the wafer. For example: thermal conductivity of the wafer is the same as a thermal conductivity of the layer; and/or a thermal expansion coefficient of the wafer is the same as a thermal expansion coefficient of the layer. A resistivity to dry etching of the wafer may be the same as a resistivity to dry etching of the layer. A resistivity to plasma etching of the wafer may be the same as a resistivity to plasma etching of the layer. A resistivity to etching herein is measured for example as a volume of material etched per a unit time and is dependent on the etching technique. Where a comparison between thermal conductivities, thermal expansion coefficients, resistivities to etching is made herein, the same conditions, such as pressure or etchant are assumed. The same herein is less than at least one of 1; 2; 5; 10; 20; or 50 percent greater than or lesser than. The same thermal conductivities, thermal expansion coefficients, resistivities to dry etching, resistivities to wet etching, and/or resistivities to plasma etching of the layer and the wafer may simplify processing of the wafer, simplify fabrication of a circuit on the second surface of the wafer and/or increase performance of a circuit on the second surface of the wafer.

In various examples providing the layer and/or providing the electrically-insulative wafer comprises at least one of: surface passivation, photolithography, ion implantation, etching, dry etching, ion etching, wet etching, buffered oxide etching, plasma ashing, thermal treatment, annealing, thermal oxidation, chemical vapor deposition, atomic layer deposition, laser lift-off, electrochemical deposition, electroplating, physical vapor deposition, or chemical-mechanical polishing. Etching may be used to remove at least part of the layer and not all of the layer, as the skilled person will appreciate.

In various examples, the method comprises epitaxially forming at least part of the layer on the first surface. Metalorganic vapour-phase epitaxy (MOVPE) or molecular beam epitaxy (MBE) may be used to epitaxially form the layer. Other epitaxy techniques are envisaged. The method may comprise bonding at least part of the layer to the first surface. Bonding, for example, comprises forming a chemical bond, forming a mechanical bond, fusion bonding, gold thermocompression, anodic bonding, thermal processing, photocuring, exposure to a catalyst, and/or application of pressure. Other bonding techniques are envisaged.

Processing of the second surface may include various techniques, e.g., bonding a layer to the second surface, etching and/or other techniques, e.g., to fabricate a circuit. Fabricating a circuit on the second surface may comprise at least one of etching, epitaxy, dry etching, plasma etching or lithography. For example, fabricating the circuit comprises at least one of: etching at least part of the second surface to at least partly form the circuit; etching at least part of an etch-precursor to the circuit to at least partly form the circuit, the etch-precursor on the second surface; lithography of at least part of the second surface to at least partly form the circuit; lithography of at least part of a lithography-precursor to the circuit to at least partly form the circuit, the lithography-precursor on the second surface; epitaxially forming at least part of the circuit on the second surface; or epitaxially forming a precursor to the circuit on the second surface. A precursor is a precursor to the circuit. An etch precursor is, for example, a etch resist. A lithography precursor is, for example a lithographic resist.

The circuit may be at least one of: a PIC or an electrical integrated circuit (IC). Other circuits are envisaged. The circuit may comprise at least one of: silicon, gallium, germanium, lithium niobate, graphene, indium, or an alloy, oxide, nitride, or phosphide of at least one of such. The skilled person will readily understand how to form a circuit on the second surface, e.g., using techniques such as: metalorganic vapour-phase epitaxy, surface passivation, photolithography, ion implantation, etching, dry etching ion etching, wet etching, buffered oxide etching, plasma ashing, thermal treatment, annealing, thermal oxidation, chemical vapor deposition, atomic layer deposition, physical vapor deposition, molecular beam epitaxy, laser lift-off, electrochemical deposition, electroplating, or chemical-mechanical polishing.

The circuit may be a PIC or for a PIC. The circuit may be formed using a generic photonic platform. A generic photonic platform uses standardised processes for fabricating photonic components and/or standardised photonic components. Forming the circuit using a generic photonic platform may be simpler, cheaper, quicker, and have a broad range of applications. A commercially utilised material platform for PICs is indium phosphide. Optically active and passive functions may be integrated on the same chip by fabricating a PIC using an indium phosphide (InP) generic platform. Other material platforms such as silicon, gallium arsenide or lithium niobite may be utilised as a platform for PICs. A PIC may comprise hundreds of components integrated in a single chip.

Examples herein relate to method of fabricating a device, the method comprising any of the methods described herein. Further examples relate to a device obtained by a method described herein. The device may be an electronic device and/or a photonic device. The first surface and the second surface of a wafer obtained by a method described herein may be more planar than a wafer obtained by another method not described herein. A device obtained by a method described herein may have improved performance compared to a device obtained by known techniques not described herein.

Certain terms, techniques, and features herein are now elaborated on.

The electrostatic chuck herein may be a Coulombic electrostatic chuck or a Johnsen-Rahbek electrostatic chuck. A Coulombic electrostatic chuck comprises an electrode and an electrical insulator. The electrical insulator is configured to be between the electrode and the wafer when the electrostatic chuck is clamped to the wafer. A Johnsen-Rahbek electrostatic chuck comprises an electrode and a dielectric. The dielectric is configured to be between the electrode and the wafer when the electrostatic chuck is clamped to the wafer. An electrostatic chuck may comprise a monopole, a dipole or a bipole for the application of the electrical field, such electrostatic chucks may be called a monopolar electrostatic chuck, a dipolar electrostatic chuck or a bipolar electrostatic chuck respectively. Electrostatic clamping and/or fabricating a circuit on an electrostatically clamped wafer may comprise flowing of a fluid over the wafer. The fluid may be an inert gas such as helium. Electrostatically clamping by applying an electric field to the electrostatic chuck may comprise applying an electromotive force to an electrode or electrodes of the electrostatic chuck. The electromotive force for electrostatic clamping while not flowing of a fluid over the wafer is, for example, greater than at least one of 400 Volts, 500 Volts, 700 Volts, 1000 Volts, 1500 Volts, 5000 Volts, or 10000 Volts. The electromotive force applied to an electrode or electrodes of an electrostatic chuck for electrostatic clamping with a flow of a fluid over the wafer is, for example, greater than at least one of 700 Volts, 800 Volts, 1000 Volts, 1500 Volts, 5000 Volts, or 10000 Volts. A Volt (V) is a kilogram metre squared per second cubed per Ampere (kg·m²·s⁻³·A⁻¹). The electrostatic chuck may be removed from the layer (or electrostatically un-clamped) by reducing the electric field applied to at least one of the electrostatic chuck or the layer, for example by reducing the electromotive force applied to an electrode or electrodes of the electrostatic chuck. A mechanical force may be used to remove the electrostatic chuck from the layer.

The wafer herein may also be considered to be a slice, a substrate or a chip. The term wafer is used herein to denote a relatively thin (e.g., planar) portion of material and may be crystalline. A wafer may be a disc of crystalline semiconductor or dielectric for use in a semiconductor fabrication plant, such as a 300 millimetre disc of silicon. A wafer may be a disc of crystalline InP for use in a semiconductor fabrication plant. A wafer may be a 25 millimetre, 51 millimetre, 76 millimetre, 100 millimetre, 200 millimetre or 300 millimetre diameter disc.

The wafer herein is, for example, a single layer of the same homogenous material, though it is envisaged for other examples that a wafer instead comprises one or more sub-layers or portions each deposited or formed independently of each other (for example one after another during a fabrication process to form a stack of layers which together could be considered a wafer). A wafer may comprise portions of different materials, for example for fabrication.

The wafer herein may be a semiconductor, a III-V semiconductor, a polymer, and/or a dielectric. The wafer may comprise at least one of: silicon, gallium, germanium, lithium niobate, graphene, indium, or an alloy, oxide, nitride, or phosphide of at least one of such. The wafer comprises an electrical-insulator, which may be an electrically-insulative material and/or an electrically-insulative structure. The wafer may reduce or prevent electrical crosstalk and/or conductance of ions and/or electrons between the first surface and the second surface. An electrical conductivity of the wafer at 20 Celsius (293 Kelvin) may be less than at least one of 0.00001 Siemens per metre, 0.0001 Siemens per metre, 0.001 Siemens per metre, 0.01 Siemens per metre, 0.1 Siemens per metre, 1 Siemens per metre, or 10 Siemens per metre. A Siemens per metre (S/m) is an Ampere squared second cubed per kilogram per metre cubed (kg⁻¹·m⁻³·s³·A²). An electrical resistivity of the wafer at 20 Celsius (293 Kelvin) may be more than at least one of 0.1 Ohm metres, 1 Ohm metres, 10 Ohm metres, 100 Ohm metres, 1000Ohm metres, 10000 Ohm metres, or 100000 Ohm metres. An Ohm metre (Ω·m) is a kilogram metre cubed per Ampere squared per second cubed (kg·m³·s⁻³·A⁻²).

The layer herein may be a single layer of the same homogenous material, though it is envisaged for other examples that a layer instead comprises one or more sub-layers or portions each deposited or formed independently of each other (e.g., one after another during a fabrication process to form a stack of sub-layers which together could be considered a layer). A layer may have sub-portions of different materials, for example, for fabrication. Sub-portions of a layer may have different dopant concentrations.

Metal elements herein are elements that are not: hydrogen, helium, boron, carbon, nitrogen, oxygen, fluorine, neon, silicon, phosphorous, sulfur, chlorine, argon, germanium, arsenic, selenium, bromine, krypton, antimony, tellurium, iodine, xenon, or radon. A metal element can be considered as an element that when isolated at 293 Kelvin is a metallic material. A metal element is, for example, indium, gallium, tin, lithium, niobium, zinc or iron. Metalloid elements are not considered as metal elements.

The non-metallic electrically-conductive material, for example, comprises at least one of: a semiconductor, a dielectric, an n-type semiconductor, a metalloid, a III-V semiconductor, silicon, gallium, germanium, lithium niobate, graphene, indium, or an alloy, oxide, nitride, or phosphide of at least one of such. The wafer may comprise indium phosphide and the layer may comprise n-doped indium phosphide. Metalloids herein are boron, silicon, germanium, arsenic, antimony, and tellurium. The non-metallic electrically-conductive material may be an electrically-conductive material and/or an electrically-conductive structure. In some examples, the electrical-conductivity of the layer does not reduce or prevent electrical crosstalk and/or significant conductance of ions and/or electrons across the layer. The electrical-conductivity of the layer at 20 Celsius (293 Kelvin) may be more than at least one of 0.1 Siemens per metre, 1 Siemens per metre, 10 Siemens per metre, 100 Siemens per metre, 1000 Siemens per metre, 10000 Siemens per metre, or 100000 Siemens per metre. A Siemens per metre (S/m) is equal to an Ampere squared second cubed per kilogram per metre cubed (kg⁻¹·m⁻³·s³·A²). The electrical resistivity of the layer at 20 Celsius (293 Kelvin) may be less than at least one of 0.00001 Ohm metres, 0.0001 Ohm metres, 0.001 Ohm metres, 0.01 Ohm metres, 0.1 Ohm metres, 1 Ohm metres, or 10 Ohm metres. An Ohm metre (Ω·m) is equal to a kilogram metre cubed per Ampere squared per second cubed (kg·m³·s⁻³·A⁻²).

It is to be understood that any feature described in relation to any one example may be used alone, or in combination with other features described, and may also be used in combination with one or more features of any other of the example, or any combination of any other of the examples. Furthermore, equivalents and modifications not described above may also be employed without departing from the scope of the accompanying claims.

What is claimed is:

1. A method comprising:
providing an electrically-insulative wafer comprising a first surface, and a second surface for processing; and
providing a layer on the first surface, wherein the layer is non-metallic, electrically-conductive, and for electrostatically clamping to an electrostatic chuck.

2. The method of claim 1, comprising epitaxially forming at least part of the layer on the first surface.

3. The method of claim 1, comprising bonding at least part of the layer to the first surface.

4. The method of claim 1, wherein the layer comprises a non-metallic electrically-conductive material comprising at least one metal element.

5. The method of claim 1, wherein the layer comprises at least one of: a semiconductor, a III-V semiconductor, an n-doped semiconductor, or a dielectric.

6. The method of claim 1, comprising electrostatically clamping the layer to the electrostatic chuck.

7. The method of claim 6, wherein after electrostatically clamping the layer to the electrostatic chuck, the first surface and the second surface are planar.

8. The method of claim 6, comprising removing the electrostatic chuck from the layer.

9. The method of claim 1, comprising fabricating a circuit on the second surface.

10. The method of claim 9, comprising at least one of:
etching at least part of the second surface to at least partly form the circuit;
etching at least part of an etch-precursor to the circuit to at least partly form the circuit, the etch-precursor on the second surface;
lithography of at least part of the second surface to at least partly form the circuit;
lithography of at least part of a lithography-precursor to the circuit to at least partly form the circuit, the lithography-precursor on the second surface;
epitaxially forming at least part of the circuit on the second surface; or epitaxially forming a precursor to the circuit on the second surface.

11. The method of claim 9, wherein the circuit is at least one of an integrated circuit or a photonic integrated circuit.

12. The method of claim 1, wherein the method comprises etching and the layer comprises an etch resist.

13. The method of claim 1, wherein at least one of:
a thermal conductivity of the electrically-insulative wafer is the same as a thermal conductivity of the layer;
a thermal expansion coefficient of the electrically-insulative wafer is the same as a thermal expansion coefficient of the layer;
a resistivity to dry etching of the wafer is the same as a resistivity to dry etching of the layer; or
a resistivity to plasma etching of the electrically-insulative wafer is the same as a resistivity to plasma etching of the layer.

14. The method of claim 1, comprising:
providing a precursor to the layer and the electrically-insulative wafer, the precursor comprising a first portion and a second portion; and
doping at least one of the first portion or the second portion to form the layer from the first portion of the precursor and the electrically-insulative wafer from the second portion of the precursor.

15. The method of claim 1, wherein at least one of:
a stiffness of the layer is greater than a stiffness of the electrically-insulative wafer; or
a heat capacity of the layer is greater than a heat capacity of the electrically-insulative wafer.

16. The method of claim 1, comprising at least partly removing the layer from the electrically-insulative wafer or removing the layer from the electrically-insulative wafer.

17. The method of claim 1, wherein at least one of:
a portion of the layer is anti-reflective;
the electrically-insulative wafer comprises at least one of a dielectric, a semiconductor, a III-V semiconductor, silicon, or indium phosphide; or
the electrically-insulative wafer comprises indium phosphide and the layer comprises n-doped indium phosphide.

18. A structure obtained by the method of claim 1.

19. A method of fabricating a device, the method comprising:
providing an electrically-insulative wafer comprising a first surface, and a second surface for processing; and
providing a layer on the first surface, wherein the layer is non-metallic, electrically-conductive, and for electrostatically clamping to an electrostatic chuck.

20. A device obtained by the method of claim 19.
